(19) United States
(12) Patent Application Publication
(10) Pub. No.: US 2026/0002995 A1
(43) Pub. Date: Jan. 1, 2026

(54) SELF LEARNING FAULT DETECTION FOR ELECTRICAL MOTORS

(71) Applicant: EATON INTELLIGENT POWER LIMITED, Dublin 4 (IE)

(72) Inventors: Ruth QUINN, Wexford (IE); Julia O'CONNELL, Dublin (IE); James Patrick RYLE, Dublin (IE); Mudi JIANG, Dublin (IE); Padhraig RYAN, Kilkenny (IE); Michael Paul NOWAK, Milwaukee, WI (US); Steven Andrew DIMINO, Wauwatosa, WI (US)

(21) Appl. No.: 18/881,451

(22) PCT Filed: Jul. 28, 2022
(86) PCT No.: PCT/EP2022/071219

§ 371 Date: Jan. 6, 2025

(51) Int. Cl. G01R 31/34; G01M 7/00; G06F 18/2413

(52) U.S. Cl. CPC G01R 31/34; G01M 7/00; G06F 18/24137

(57) ABSTRACT

Some embodiments relate to a method and system for determining electrical motor fault comprising: measuring ambient vibration data of the electrical motor and performing spectral processing of the ambient vibration data; filtering noise data from the ambient vibration data, outputting a filtered ground truth vibration spectrum, clustering features of the filtered ground truth vibration spectrum, and determining temporal and spatial distance between the clustered features; measuring electrical data signals of the electrical motor, analysing the electrical data signals to extract features of the electrical data signals and storing the extracted features from the electrical data signal; assigning an operating state label to the ground truth vibration spectrum by comparing the clustered features of the ground truth operational vibration spectrum to a database of stored training data and ground truth algorithms; determining an accuracy of the operating state label; and determining electrical motor fault using a new measured electrical data signal and the stored ground truth algorithm to determine if the electrical motor is in a fault state.

### CROSS-REFERENCE TO RELATED APPLICATIONS

This application is a national phase filing under 35 C.F.R. § 371 of and claims priority to PCT Patent Application No. PCT/EP2022/071219, filed on Jul. 28, 2022, the contents of which are hereby incorporated in its entirety by reference herein.

### FIELD OF THE DISCLOSURE

The presently disclosed subject matter relates to a method and system of electrical motor fault detection.

### BACKGROUND OF THE DISCLOSURE

Poor operating conditions can drastically shorten the life of a motorised system, requiring corrective maintenance and unexpected downtime.

For virtually any motor-driven system, the control of mechanical vibration and noise is a critical design factor that can significantly impact the system's performance, reliability, cost, safety and suitability for use. Uncontrolled physical vibrations can degrade the system's overall efficiency, accelerate material fatigue and compound the natural rate of wear on friction surfaces.

To extend the life of these systems, fault detection using vibration analysis can be used to infer if the motor is operating under harmful conditions and can pre-emptively warn if the system is going to require corrective maintenance. However, vibration analysis generally requires continuous monitoring of high sample rate data requiring large quantities of storage, high rates of computation and high-power consumption. In addition, there are associated maintenance costs and potential failure points.

Therefore, an aim of the presently disclosed subject matter is to overcome some or all of these deficiencies.

### SUMMARY OF THE DISCLOSURE

According to a first aspect, there is provided an electrical motor fault determining method, comprising: measuring ambient vibration data of the electrical motor and performing spectral processing of the ambient vibration data; filtering noise data from the ambient vibration data, outputting a filtered ground truth vibration spectrum, clustering features of the filtered ground truth vibration spectrum, and determining temporal and spatial distance between the clustered features; measuring electrical data signals of the electrical motor, analysing the electrical data signals to extract features of the electrical data signals and storing the extracted features from the electrical data signal; assigning an operating state label to the ground truth vibration spectrum by comparing the clustered features of the ground truth operational vibration spectrum to a database of stored training data and ground truth algorithms; determining an accuracy of the operating state label; and determining electrical motor fault using a new measured electrical data signal and the stored ground truth algorithm to determine if the electrical motor is in a fault state.

Preferably, the noise data comprises vibration data of the ambient vibration data unrelated to the filtered ground truth vibration spectrum.

Preferably, measuring the ambient vibration data further comprises monitoring the electrical motor during two or more operating phases, wherein the operating phases are one selected from the range of start-up, idling, active operation, and powering down phases of the electrical motor.

Preferably, when a power consumption of the electrical motor is below a preset power level, reading additional sensors and aligning the data captured form the additional sensors in time.

Preferably, the additional sensors comprise one or more of an acoustic sensor or an optical sensor.

Preferably, the acoustic sensor comprises one or more sound transducers; and the optical sensor comprises one selected from the range of a non-contact free space optical element or a fibre-based optical element.

Preferably, the processed ambient vibration data is stored in a data store.

Preferably, filtering comprises using digital signal processing techniques or machine learning disaggregation methods.

Preferably, the clustering is of at least one of the features of frequency, amplitude and waveform shape.

Preferably, determining temporal and spatial distance between the clustered features comprises identifying the centroid of each cluster, determining the distance between the centroid of each cluster, and determining an optimal number of clusters based on an analysis of the distance between the clusters.

Preferably, the electrical signal is an AC electrical signal.

Preferably, the assigning an operating state label to the ground truth vibration spectrum comprises: determining a similarity score to determine whether to directly assign an operating state label, to execute an existing ground truth algorithm or to train a new ground truth algorithm using machine learning.

Preferably, the assigning an operating state label to the ground truth vibration spectrum further comprises: determining if the similarity score exceeds a lower threshold and an upper threshold and if the similarity score exceeds the upper threshold then an operating state label is directly assigned, if the similarity score exceeds the lower threshold but does not exceed the upper threshold, then the existing ground truth algorithm is executed, and if the similarity score does not exceed either the upper or lower thresholds, then a new ground truth algorithm is trained using machine learning.

Preferably, when it is determined to train a new ground truth algorithm using machine learning, then the training comprises: labelling the stored extracted features of the electrical data signals using the ground truth vibration spectrum and outputting a trained machine learning model to be stored as a ground truth algorithm.

Preferably, training the machine learning model comprises: (a) collecting labelled electrical data signals for a new cluster; (b) defining a hyper-parameter search space; (c) training a new machine learning model to be stored as a ground truth algorithm; and (d) determining an accuracy of the new machine learning model, wherein if the accuracy is above a preset accuracy level, then storing the new machine learning model in a database of machine learning models as a ground truth algorithm, and if the accuracy is below the preset criteria then repeating the steps (a) to (c) until the accuracy is above the preset accuracy level; and wherein the accuracy is determined by comparing the labelled electrical data signals with the new machine learning model which is stored as a ground truth algorithm.

Preferably, the upper and lower thresholds are adjusted based on determining if the accuracy of the direct labelling of the operational state label is above a predefined accuracy; and if the accuracy is not above the predefined accuracy then increasing the similarity score's upper threshold and lower threshold.

Preferably, if a fault state is detected with the electrical motor, then accessing a predefined resolutions database to determine how to resolve the fault state, and if a resolution is found in the predefined resolutions database then performing that resolution.

According to a second aspect of the presently disclosed subject matter, there is provided an electrical motor fault determination system according to the method of the first aspect of the presently disclosed subject matter, the system comprising: a device comprising the electrical motor, vibration sensors and electrical sensors; and an external device configured to train a new ground truth algorithm using machine learning.

Preferably, the device comprises one of a motorised pump device, a vehicle, or an industrial tool.

Preferably, the external device is one of an external server or a centralised repository.

### DETAILED DESCRIPTION OF DRAWINGS

Embodiments of the presently disclosed subject matter will now be described by way of example only and with reference to the accompanying drawings, in which:

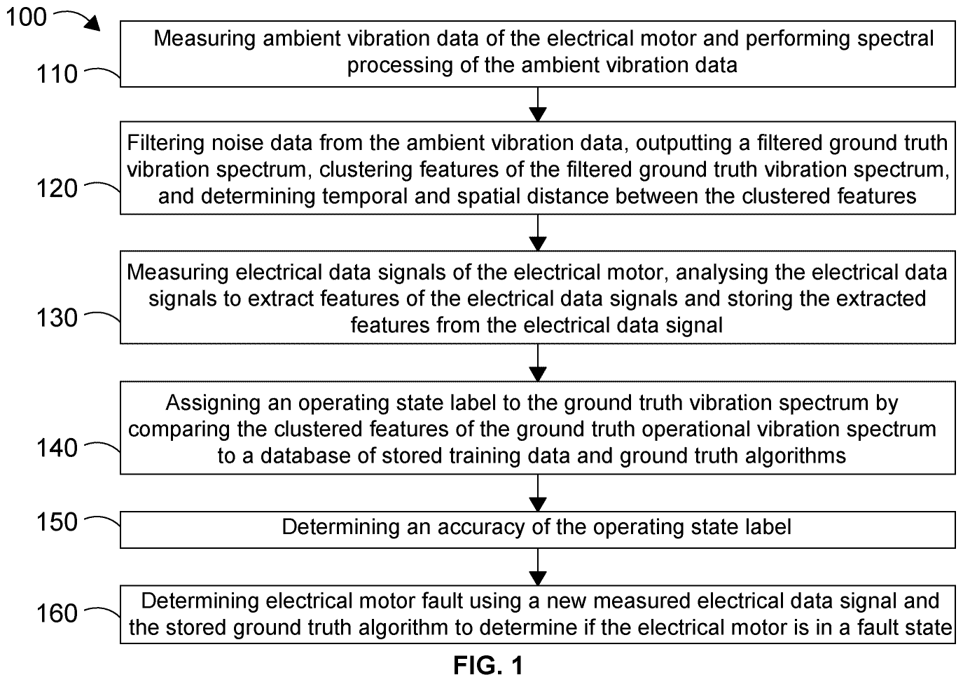

FIG. 1 depicts an electrical motor fault detection method in accordance with a first aspect of the presently disclosed subject matter.

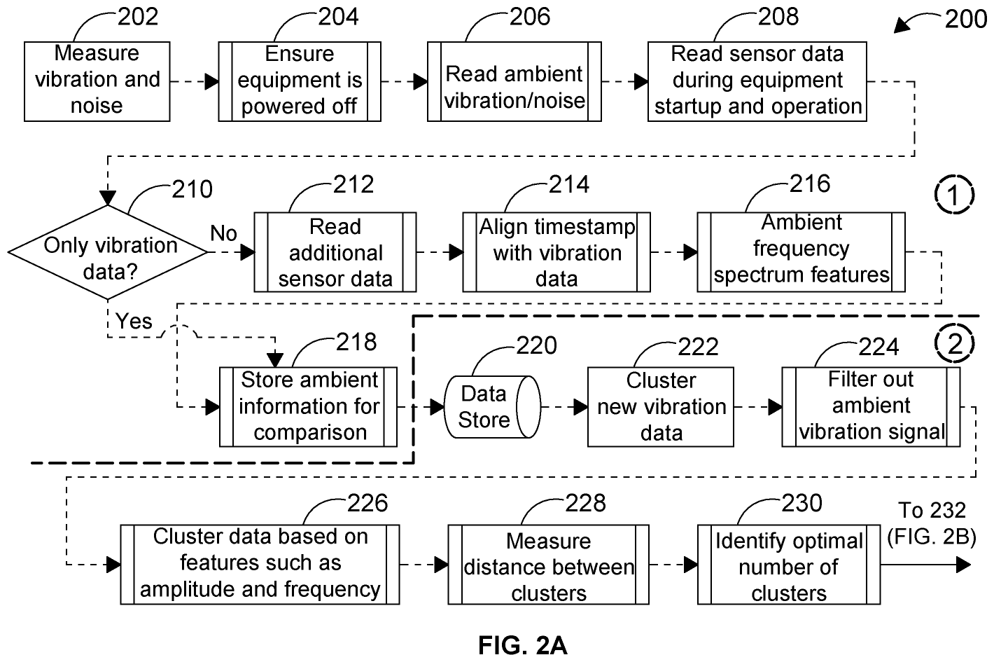

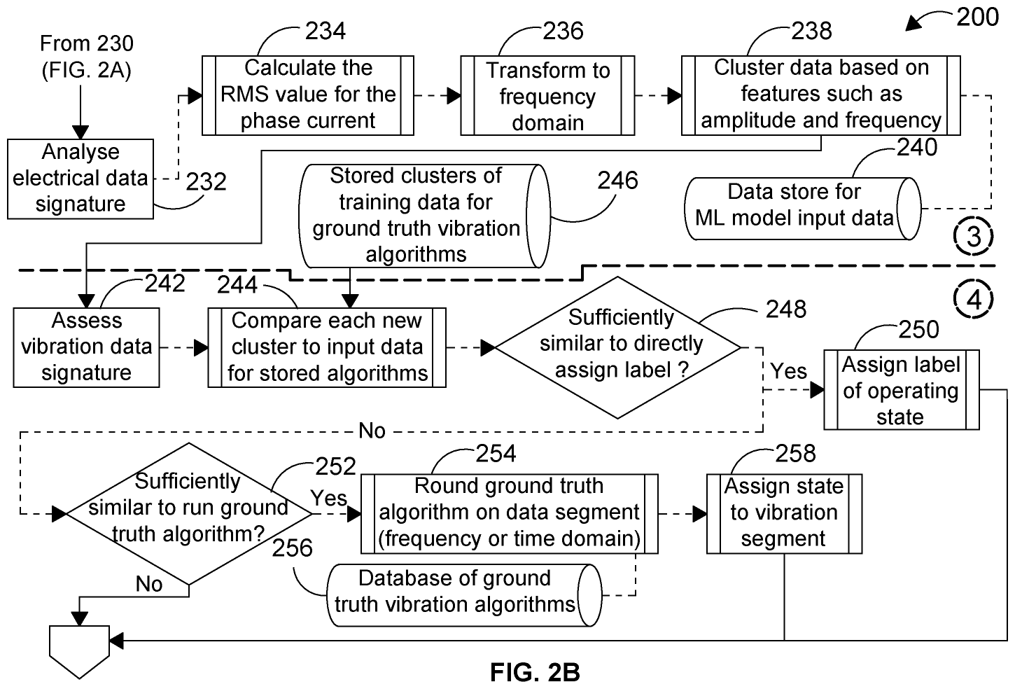

FIG. 2A depicts further aspects of the electrical motor fault detection method in accordance with the first aspect of the presently disclosed subject matter.

FIG. 2B depicts further aspects of the electrical motor fault detection method in accordance with the first aspect of the presently disclosed subject matter.

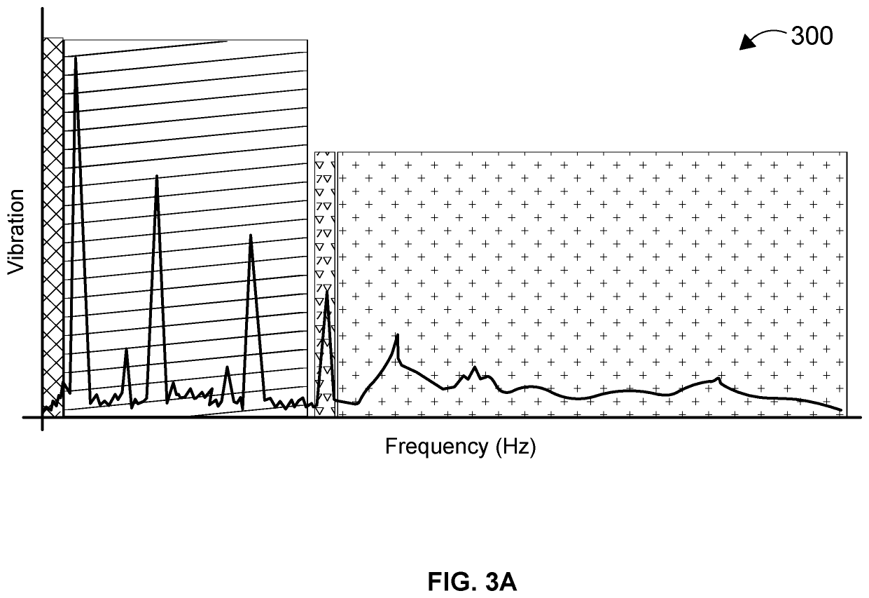

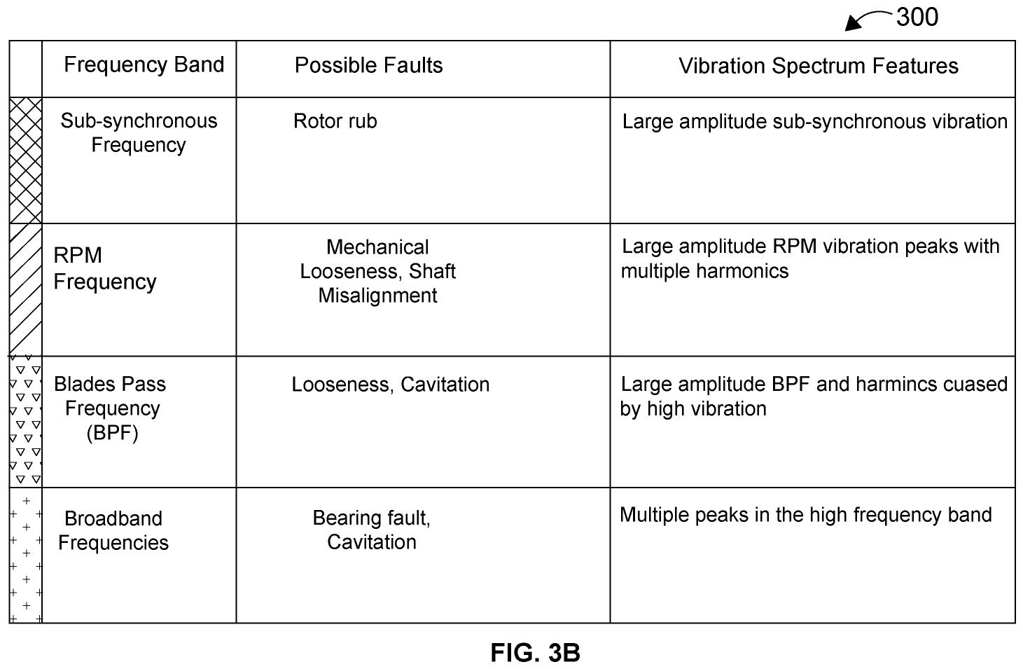

FIG. 3A depicts an example vibration data spectrum as a function of frequency depicting clustered features of the vibration data spectrum.

FIG. 3B depicts a table comprising a result of the vibration data spectrum analysis.

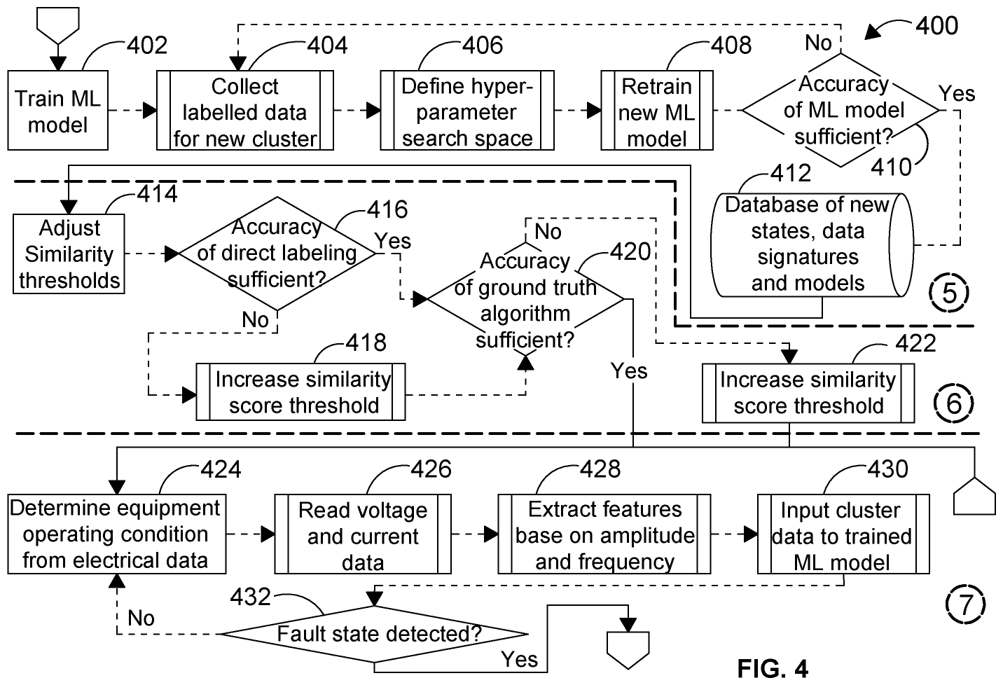

FIG. 4A depicts further aspects of the electrical motor fault detection method in accordance with the first aspect of the presently disclosed subject matter.

FIG. 4B depicts further aspects of the electrical motor fault detection method in accordance with the first aspect of the presently disclosed subject matter.

Figure SA depicts a method of identifying a severity of a detected fault state and determining a resolution to the fault state.

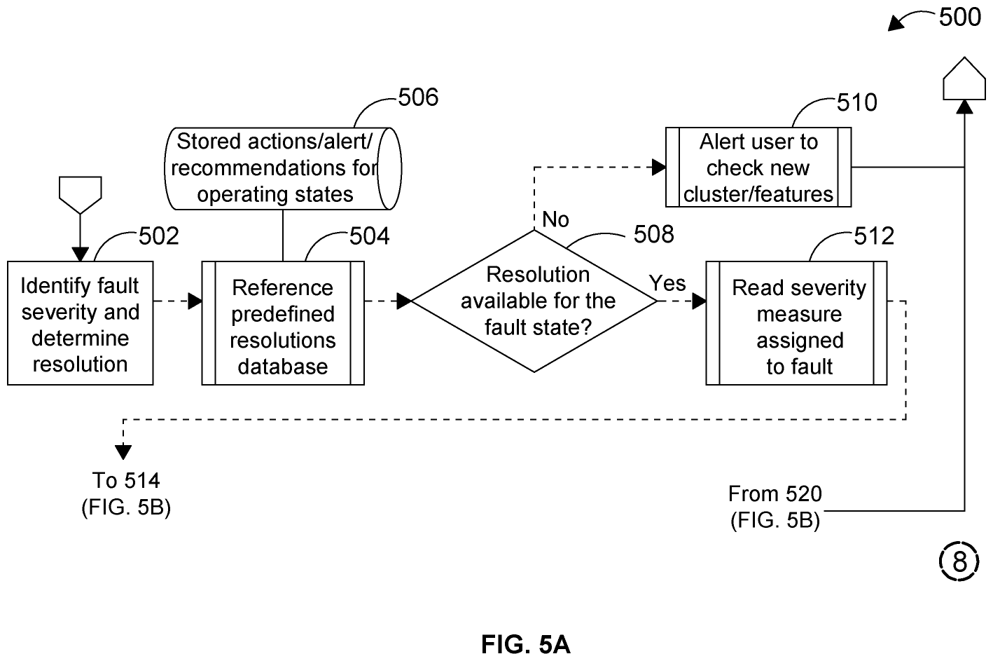

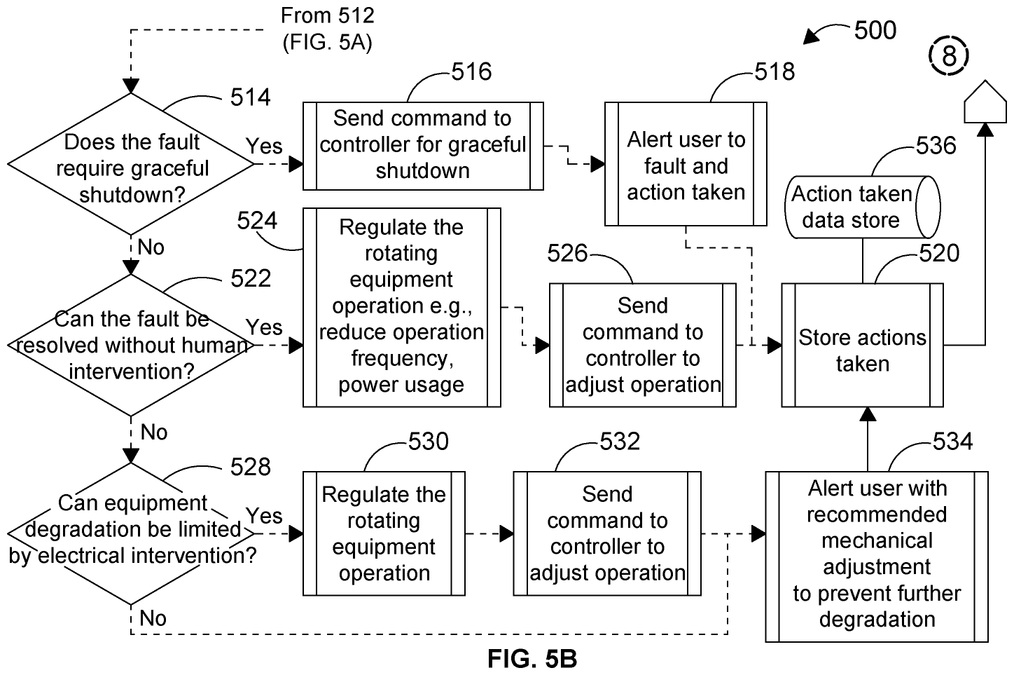

FIG. 5B depicts further aspects of the method of identifying a severity of a detected fault state and determining a resolution to the fault state.

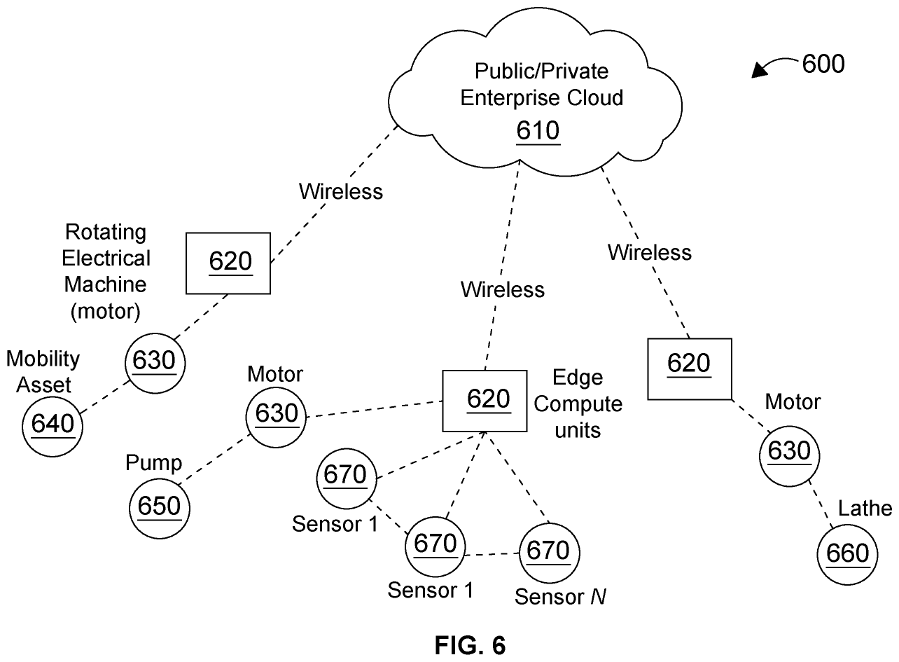

FIG. 6 depicts an electrical motor fault detection system in accordance with a second aspect of the presently disclosed subject matter.

With reference to FIG. 1, this depicts an electrical motor fault detection method, comprising steps 110 to 160. Step 110 comprises measuring ambient vibration data of the electrical motor and performing spectral processing of the ambient vibration data. Step 120 comprises filtering noise data from the ambient vibration data, outputting a filtered ground truth vibration spectrum, clustering features of the filtered ground truth vibration spectrum, and determining temporal and spatial distance between the clustered features. Step 130 comprises measuring electrical data signals of the electrical motor, analysing the electrical data signals to extract features of the electrical data signals and storing the extracted features from the electrical data signal. Step 140 comprises assigning an operating state label to the ground truth vibration spectrum by comparing the clustered features of the ground truth operational vibration spectrum to a database of stored training data and ground truth algorithms. Step 150 comprises determining an accuracy of the operating state label; and step 160 comprises determining electrical motor fault using a new measured electrical data signal and the stored ground truth algorithm to determine if the electrical motor is in a fault state.

With reference to FIGS. 2A to 2B, these depict further aspects of the electrical motor fault detection method, comprising steps 202 to 258, where FIG. 2A comprises steps 202-230 and FIG. 2B comprises steps 232-258.

Step 202 comprises measuring vibration and noise. Measuring vibration and noise comprises measuring ambient vibration around a device comprising an electrical motor while the electrical motor is turned on. Step 204 comprises ensuring whether equipment is powered off; and step 206 comprises reading the ambient vibration and noise when the equipment is turned off (i.e. powered off). Step 208 comprises reading sensor data (i.e. vibration sensor data) during equipment start up and operation. Therefore, steps 202 to 208 comprise the measurement of vibration (e.g. using a vibration sensor) during start-up, idling, active mode, and powering down phase of the electrical motor.

In step 210, it is determined whether it is only vibration data which is required, or whether additional sensor data (e.g. from at least one acoustic sensor or at least one light sensor) is required. If only vibration data is required then the method proceeds to step 218. If additional sensor data is required then the method proceeds to steps 212 to 216, before proceeding to step 218. Step 212 comprises reading the additional sensor data, when it is determined that the additional sensor data is required. Step 214 comprises aligning timestamps of the additional sensor data with the vibration data (i.e. aligning measurements/data points from the additional sensors in time to compensate for different sampling rates of the additional sensors). Step 216 comprises performing spectral processing of the ambient frequency spectrum features from the additional sensor data. Step 218 comprises storing the ambient information (e.g. either the ambient vibration data or the ambient vibration data and additional sensor data). The information stored in step 218 is stored in a data store, as depicted in step 220.

Step 222 comprises clustering new vibration data. Step 224 comprises filtering out the ambient vibration signal. Step 226 comprises clustering the data (e.g. vibration data) based on particular features of the data, such as signal amplitude and frequency. Step 228 comprises measuring a distance between the clusters. Step 230 comprises identifying an optimal number of clusters.

Steps 232 to 240 depict analysing and extracting features associated with a detected electrical signal. Step 232 comprises analysing the electrical data signal (e.g. a time varying AC electrical signal). Step 234 comprises calculating a root means squared (RMS) value for the electrical signal. Step 236 comprises performing a transformation (i.e. a Fourier transformation) to transform the electrical data signal into the frequency domain. Step 238 comprises clustering features of the electrical data signal, based on features such as amplitude and frequency. The results of step 238 are stored in a data stored for machine learning model input data, as depicted in step 240.

Steps 242 to 258 relate to assigning an operating state label to the ground truth vibration spectrum (as depicted in FIG. 3A) by comparing the clustered features of the ground truth operational vibration spectrum to a database of stored training data and ground truth algorithms (as depicted in FIGS. 3B and 3C). Step 242 comprises assessing the vibration data spectrum. Step 244 comprises comparing each new cluster to input data for stored ground truth algorithms. The input data for stored ground truth algorithms is retrieved from a data store of stored clusters of training data for ground truth vibration algorithms, as depicted in step 246. Step 248 comprises assessing whether to directly assign an operating state label, by determining whether any of the stored ground truth algorithms are sufficiently similar to the new data. If it is determined in step 248 that the any of the stored ground truth algorithms are sufficiently similar to the new data then the method proceeds to step 250, where step 250 comprises directly assigning an operating state label. Otherwise, the method proceeds to step 252. Step 252 comprises determining if each new cluster is sufficiently similar to the input data for any of the stored ground truth algorithms to run any of the stored ground truth algorithms. If the result of step 252 is no then the method proceeds to a further step, as depicted in FIG. 4. If the result of step 252 is yes, then the method proceeds to step 254, where step 254 comprises the sufficiently similar ground truth algorithm being run on a data segment (where the data segment is in either frequency or time domain). The result of step 254 is stored in a database of ground truth vibration algorithms, as depicted in step 256. The method then proceeds to step 258, where step 258 comprises assigning an operating state label to the vibration segment (i.e. the segment of the vibration data spectrum).

With reference to FIG. 3A, this depicts a vibration data spectrum (i.e. vibration as a function of frequency) comprising clustered features of the vibration data spectrum. The clustered features of the vibration data spectrum (i.e. specific spectral features) are analysed to determine information regarding the electrical motor.

With reference to FIG. 3B, this depicts a table comprising a result of the vibration data spectrum analysis. It can be seen that the particular frequency bands depicted in the Table shown in FIG. 3B are also shown in the vibration data spectrum of FIG. 3A. The table of FIG. 3B comprises a column describing particular frequency bands (i.e. sub-synchronous frequency, revolutions per minute (RPM) frequency, blade pass frequency (BPF), and broadband frequencies). A second column describes particular faults (i.e. electrical motor faults) associated with the frequency bands (i.e. rotor rub, mechanical looseness/shaft misalignment, looseness/cavitation, and bearing fault/cavitation). A final column describes the types of vibration data spectrum features which are associated with these particular faults.

With reference to FIGS. 4A to 4B, these depict further aspects of the electrical motor fault detection method, comprising steps 402 to 432, where FIG. 4A comprises steps 402-422 and FIG. 4B comprises steps 424-432. Steps 402 to 412 depict training a machine learning model using vibration data to label features associated with the electrical signals, as described in relation to steps 232 to 240 of FIG. 2B.

Step 402 comprises training the machine learning model, which comprises steps 404 to 412. Step 404 comprises collecting labelled data (i.e. labelled electrical data signals) for a new cluster, which comprises data collection of a ground truth vibration spectrum to verify the operating condition of the equipment, as described in FIGS. 2A-2B. Step 406 comprises defining a hyper-parameter search space. For example, defining the number of layers of the neural network, the type of activation function or the connectivity between the layers. Step 408 comprises retraining a new machine learning model to be stored as a ground truth algorithm. Step 410 comprises determining that the accuracy of the machine learning model is sufficient. If the accuracy is found to be insufficient then the methods repeats steps 404 to 410 until it is found that it is sufficient. Where the accuracy is found to be sufficient, the method proceeds to step 412, which depicts that the result is stored in a data store of new states, data signatures and machine learning models.

Steps 414 to 422 depict a process of adjusting similarity thresholds in order to achieve the desired level of accuracy in determining an operating state label. Step 414 comprises adjusting similarity thresholds. Step 416 comprises determining whether the accuracy of direct labelling is sufficient. If the accuracy is sufficient then the method proceeds to step 420 and if not then the method proceeds to step 418 prior to step 420. In step 418, when it is determined that the accuracy of direct labelling is not sufficient, this comprises a similarity score threshold, where the similarity score is preset. By adjusting the similarity score threshold the predictive accuracy of the machine learning model is increased. Step 420 comprises determining if the accuracy of the ground truth algorithm is sufficient. If the result of step 420 is no, then the method proceeds to step 422, where step 422 comprises further increasing the similarity score threshold and the method then proceeds to step 424. If the result of step 420 is yes, then the method proceeds to step 424.

Steps 424 to 432 depict the determination of equipment operation (i.e. electrical motor operation state or electrical motor operation fault state) based on the electrical data signal and using a ground truth algorithm, for example by using an existing ground truth algorithm or by training a new ground truth algorithm using machine learning. Step 424 comprises determining the equipment (e.g. electrical motor) operating condition using the electrical data signal. Step 426 comprises reading the voltage and current data from the electrical data signal. Step 428 comprises extracting features based on the amplitude and frequency of the electrical data signal. Step 430 comprises inputting clustered electrical data signal data to the ground truth algorithm (e.g. the trained machine learning model). Step 432 comprises determining, using the algorithm described in relation to step 430, whether a fault state is detected. When a fault state is detect, the method proceeds to a method as depicted in Figures SA-5B. If no fault state is detected, the method returns to step 424 and the algorithm continues to determine whether a fault state is detected using the electrical data signal.

With reference to Figures SA to 5B, these depict a method of identifying a severity of a detected fault state and determining a resolution to the fault state, as depicted in steps 502 to 534, where Figure SA comprises steps 502-512 and FIG. 5B comprises steps 514-536. The method of steps 502 to 534 relate to accessing a predefined resolutions database to determine how to resolve the fault state, and if a resolution is found in the predefined resolutions database then performing that resolution.

Step 502 comprises identifying fault severity and determining a resolution. Step 504 comprises referencing a predefined resolutions database, the database depicted in step 506, which depicts a database of stored actions, alerts, and/or recommendations for operating states. Step 508 comprises determining if there is a predefined resolution available from the predefined resolutions database. If no resolution is determined, then the method proceeds to step 510, which comprises alerting the user to check the fault. If a resolution is determined in step 508, then the method proceeds to step 512, which comprises reading an assigned severity measured which has been assigned to the determined fault state. Step 514 comprises determining, based on the severity measure from step 512, whether the fault state requires a shutdown of the equipment (i.e. electrical motor). If the result of step 514 is yes, then the method proceeds to steps 516 to 518. Step 516 comprises sending the command for shutdown to the equipment controller, and step 518 comprises altering the user of the fault and the action taken and the method proceeds to step 520, described below.

If the result of step 514 is no, then the method proceeds to step 522. Step 522 comprises determining whether the fault can be resolved without human intervention. If the result of step 522 is yes, then the methods proceeds to steps 524 to 526. Step 524 comprises regulating the electrical motor equipment's operation, for example by reducing the operation frequency and/or power usage of the electrical motor. Step 526 comprises sending a command to the controller to adjust operation and the method proceeds to step 520, described below.

If the result of step 522 is no, then the method proceeds to step 528. Step 528 comprises determining whether the electrical motor equipment fault (i.e. degradation) be limited by performing an electrical intervention. If the result of step 528 is yes, then the method proceeds to steps 530-532 before proceeding to step 534. If the result of step 528 is no, the method proceeds straight to step 534. Step 530 comprises regulating the electrical motor equipment operation, and step 532 comprises sending a command to the electrical motor equipment controller to adjust the operation. Step 534 comprises alerting the user with recommended mechanical adjustments to prevent further fault (i.e. degradation) with the electrical motor, and the method proceeds to step 520.

Step 520, described above as following steps 518, 526 or 532, comprises storing the actions taken. The actions are stored in an actions taken database, as depicted in step 536.

With reference to FIG. 6, this depicts a system 600 in accordance with a second aspect of the presently disclosed subject matter.

The system 600 comprises a public/private enterprise cloud 610 (i.e. cloud computing or a centralised repository). The cloud 610 is wirelessly connected to a plurality of edge devices 620 (e.g. equipment 640, 650, 660 comprising an electrical motor 630). The equipment shown in the system 600 of FIG. 6 comprises a mobility asset 640, a pump 650 and a lathe 660. The edge device 620 connected to the pump 650 is further connected to a plurality of sensors 670 (sensor 1, sensor 2, . . . sensor N).

It will be appreciated that the above described embodiments of the first and second aspects of the presently disclosed subject matter are given by way of example only, and that various modifications may be made to the embodiments without departing from the scope of the presently disclosed subject matter as defined in the appended claims.

For example, in use the noise data of step 120 of FIG. 1 may comprise vibration data of the ambient vibration data unrelated to the filtered ground truth vibration spectrum.

Step 210 of FIG. 2A may comprise determining that additional sensors are required. The additional sensors may comprise acoustic noise and/or light sensors. For example, a pump cavitation phenomenon may occur in an AC electrical motor. In the case of pump cavitation in centrifugal pumps, this may be characterised by acoustic noise, light emission and shock-wave impact of a pump impeller. This can be detected using acoustic sensors, light sensors and vibration sensors respectively. Therefore, the additional sensors described in relation to FIGS. 2A-2B may comprise one or more of acoustic sensors and/or light sensors, in addition to the vibration sensors described in relation to FIGS. 2A-2B. In particular, the acoustic sensor may comprise one or more sound transducers. The optical sensor may comprise one or more selected from the range of a non-contact free space optical element or a fibre-based optical element.

Step 220 comprises a data store. The data store may store ambient information, where the ambient information may comprise ambient vibration data, or it may comprise ambient vibration data and additional sensor data. The data store may store relevant features of processed vibration spectral data, such as power levels and/or data vignettes. Step 222 may comprise clustering based on at least one of frequency, amplitude or waveform shape.

Step 224 may comprise filtering out the ambient vibration signal using a method such as digital signal processing techniques (e.g. low band pass or high band pass filters, Fourier analysis or wavelet analysis). Furthermore, step 224 may alternatively comprise filtering out the ambient vibration signal using a method such as using advanced machine learning enabled disaggregation methods.

Step 226 may further comprise identifying a centroid of one or more vibration spectrum features after the filtering in step 224. Step 228 may further comprise measuring a distance between the identified clusters, where the distance may be quantified using a known technique, such as by determining a squared Euclidean distance. Step 230 may comprise identifying the optimal number of clusters by analysis of the distance between the clusters, where each identified cluster may represent a particular operating state, as further outlined in FIGS. 3A, 3B and 3C. In steps 232 to 240, the electrical data signal may be either an AC or a DC electrical signal. In the case of AC signals, features such as a phase angle may be determined, and a spectral analysis may be performed to build a feature data set. For example, fluctuations or an increase in the side band amplitude can indicate pump cavitation, rotor fault or a bearing fault. The data store for the machine learning input model as depicted in step 240 of FIG. 2B may store the extracted features from the electrical data signal, which may be used as an input for a machine learning model.

Step 258 of FIG. 2B, which describes assigning a state (i.e. an operating state label) to a ground truth vibration (i.e. vibration segment) may further comprise determining a similarity score to determine whether to directly assign an operating state label, to execute an existing ground truth algorithm or to train a new ground truth algorithm using machine learning. Furthermore, step 258 may further comprise determining if the similarity score exceeds a lower threshold and an upper threshold and if the similarity score exceeds the upper threshold then an operating state label is directly assigned. If the similarity score exceeds the lower threshold but does not exceed the upper threshold, then the existing ground truth algorithm is executed. If the similarity score does not exceed either the upper or lower thresholds, then a new ground truth algorithm is trained using machine learning.

In step 404 of FIG. 4A, a dataset is collected to determine the operating condition, and the amount of data which is to be collected is determined by the amount of data which has been used to train pre-existing models. Alternatively, the data can be collected until a sufficiently large dataset is available to train the model to a predetermined accuracy. In step 404 of FIG. 4A, the stored extracted features of the electrical data signals may be labelled using the ground truth vibration spectrum.

In step 406, the hyper-parameter search space may be defined using a grid search process, which is used to search the hyper-parameter search space and to identify an optimal set of hyper-parameters. The models within this search space are trained, as described in step 408, and an accuracy is compared across each model, as described in step 410. A user may specify a particular metric as a measure of the accuracy, such as a precision or recall metric, or an Fl score. By allowing a user to choose the metric, the priorities of the user equipment are fulfilled. For example, in some operating conditions there may be a strong preference to avoid false negatives.

Step 410 of FIG. 4A may comprise determining an accuracy of the new machine learning model. If the accuracy is above a preset accuracy level, then the new machine learning model may be stored in a database of machine learning models as a ground truth algorithm. If the accuracy is below the preset criteria then the method may comprise repeating the steps of the method for training a machine learning model until the accuracy of the machine learning model is above a preset accuracy level. In particular, determining the accuracy in step 410 of FIG. 4A may comprise comparing the labelled electrical data signals with the new machine learning model which is stored as a ground truth algorithm.

In relation to FIG. 6, there may be a plurality of edge devices 620 as depicted in FIG. 6, or alternatively there may only be one edge device 620. The plurality of sensors 670 can include vibration sensors or additional sensors or a combination of both. The additional sensors may comprise acoustic sensors or light sensors. Alternatively, there may only be one sensor, where the sensor may include a vibration sensor or additional sensors or a combination of both. The mobility asset 640 may include any vehicle comprising an electrical motor 630, or a rotating electrical machine.

The system 600 of FIG. 6 may be configured to apply unsupervised learning (e.g. unsupervised cluster learning) to analyse, compare and predict faults of rotating electrical machines using electrical data signals. The electrical data signals may be measured using a voltage and/or current meter. The system 600 may be configured to use machine learning (wherein the machine learning may be performed using the cloud 610), which uses a combination of ambient vibration data and electrical data signals to be used by the cloud 610 in order to train a machine learning model to predict the occurrence or onset of a fault. The system 600 may be configured to use physics-based models and algorithms, producing reduced power consumption, increased efficiency, safer operations and to extend the lifetime of a machine comprising an electrical motor or a rotating machine-based device.

1. An electrical motor fault determining method, comprising:
measuring ambient vibration data of the electrical motor and performing spectral processing of the ambient vibration data;
filtering noise data from the ambient vibration data, outputting a filtered ground truth vibration spectrum, clustering features of the filtered ground truth vibration spectrum, and determining temporal and spatial distance between the clustered features;
measuring electrical data signals of the electrical motor, analysing the electrical data signals to extract features of the electrical data signals and storing the extracted features from the electrical data signal;
assigning an operating state label to the ground truth vibration spectrum by comparing the clustered features of the ground truth operational vibration spectrum to a database of stored training data and ground truth algorithms;
determining an accuracy of the operating state label; and
determining electrical motor fault using a new measured electrical data signal and the stored ground truth algorithm to determine if the electrical motor is in a fault state.

2. The method of claim 1, wherein the noise data comprises vibration data of the ambient vibration data unrelated to the filtered ground truth vibration spectrum.

3. The method of claim 1, wherein measuring the ambient vibration data further comprises monitoring the electrical motor during two or more operating phases, wherein the operating phases are one selected from the range of start-up, idling, active operation, and powering down phases of the electrical motor.

4. The method of claim 3, wherein when a power consumption of the electrical motor is below a preset power level, reading additional sensors and aligning the data captured form the additional sensors in time.

5. The method of claim 4, wherein the additional sensors comprise one or more of an acoustic sensor or an optical sensor.

6. The method of claim 5, wherein the acoustic sensor comprises one or more sound transducers; and the optical sensor comprises one selected from the range of a non-contact free space optical element or a fibre-based optical element.

7. The method of claim 1, wherein the processed ambient vibration data is stored in a data store.

8. The method of claim 1, wherein filtering comprises using digital signal processing techniques or machine learning disaggregation methods.

9. The method of claim 1, wherein the clustering is of at least one of the features of frequency, amplitude and waveform shape.

10. The method of claim 1, wherein determining temporal and spatial distance between the clustered features comprises identifying the centroid of each cluster, determining the distance between the centroid of each cluster, and determining an optimal number of clusters based on an analysis of the distance between the clusters.

11. The method of claim 1, wherein the electrical signal is an AC electrical signal.

12. The method of claim 1, wherein the assigning an operating state label to the ground truth vibration spectrum comprises:
determining a similarity score to determine whether to directly assign an operating state label, to execute an existing ground truth algorithm or to train a new ground truth algorithm using machine learning.

13. The method of claim 12, wherein the assigning an operating state label to the ground truth vibration spectrum further comprises:
determining if the similarity score exceeds a lower threshold and an upper threshold and if the similarity score exceeds the upper threshold then an operating state label is directly assigned,
if the similarity score exceeds the lower threshold but does not exceed the upper threshold, then the existing ground truth algorithm is executed, and
if the similarity score does not exceed either the upper or lower thresholds, then a new ground truth algorithm is trained using machine learning.

14. The method of claim 12, wherein when it is determined to train a new ground truth algorithm using machine learning, then the training comprises:
labelling the stored extracted features of the electrical data signals using the ground truth vibration spectrum and outputting a trained machine learning model to be stored as a ground truth algorithm.

15. The method of claim 14, wherein training the machine learning model comprises:
(a) collecting the labelled electrical data signals for a new cluster;
(b) defining a hyper-parameter search space;
(c) training a new machine learning model to be stored as a ground truth algorithm; and
(d) determining an accuracy of the new machine learning model, wherein if the accuracy is above a preset accuracy level, then storing the new machine learning model in a database of machine learning models as a ground truth algorithm, and if the accuracy is below the preset criteria then repeating the steps (a) to (c) until the accuracy is above the preset accuracy level; and
wherein the accuracy is determined by comparing the labelled electrical data signals with the new machine learning model which is stored as a ground truth algorithm.

16. The method of claim 13, wherein the upper and lower thresholds are adjusted based on determining if the accuracy of the direct labelling of the operational state label is above a predefined accuracy; and if the accuracy is not above the predefined accuracy then increasing the similarity score's upper threshold and lower threshold.

17. The method of claim 1, wherein if a fault state is detected with the electrical motor, then accessing a predefined resolutions database to determine how to resolve the fault state, and if a resolution is found in the predefined resolutions database then performing that resolution.

18. An electrical motor fault determination system according to the method of claim 1, the system comprising:
a device comprising the electrical motor, vibration sensors and electrical sensors; and
an external device configured to train a new ground truth algorithm using machine learning.

19. The system of claim 18, wherein the device comprises one of a motorised pump device, a vehicle, or an industrial tool.

20. The system claim 18, wherein the external device is one of an external server or a centralised repository.
